(19) United States
(12) Patent Application Publication
(10) Pub. No.: US 2014/0034126 A1
(43) Pub. Date: Feb. 6, 2014

(54) THIN FILM SOLAR CELL MODULE AND METHOD OF MANUFACTURING THE SAME

(71) Applicant: Samsung SDI Co., Ltd., Yongin-si (KR)

(72) Inventors: Jung-Yup YANG, Yongin-si (KR); Young-Kyoung AHN, Yongin-si (KR); Bong-Kyoung PARK, Yongin-si (KR); Yury Lebedev, Yongin-si (KR)

(73) Assignee: Samsung SDI Co., Ltd, Yongin-si (KR)

(21) Appl. No.: 13/954,001

(22) Filed: Jul. 30, 2013

Related U.S. Application Data
(60) Provisional application No. 61/677,768, filed on Jul. 31, 2012.

(51) Int. Cl. H01L 31/0216; H01L 31/18

(52) U.S. Cl. CPC H01L 31/02167; H01L 31/18
USPC 136/258; 136/252; 136/264; 136/262; 136/260; 136/259; 438/64

(57) ABSTRACT

A solar cell module includes a substrate, a lower electrode on the substrate, a light absorption layer on the lower electrode, an upper electrode on the light absorption layer, and a protective layer on the upper electrode, the protective layer extending along sidewalls of the light absorption layer to the lower electrode, the protective layer including a moisture absorbing material.

### CROSS-REFERENCE TO RELATED APPLICATION

This application claims priority to pending U.S. Provisional Application No. 61/677,768, filed in the U.S. Patent and Trademark Office on Jul. 31, 2012, and entitled “Thin Film Solar Cell Module And Method Of Manufacturing The Same,” which is hereby incorporated by reference herein in its entirety for all purposes.

### BACKGROUND

1. Field

Embodiments relate to a thin film solar cell module and a method of manufacturing the same.

2. Description of the Related Art

Currently, the depletion of existing energy resources such as oil or coal is expected to continue, and thus interest in alternative sources of energy has increased. From among these alternative sources, solar cells for directly transforming solar energy into electric energy, e.g., by using semiconductor elements, are regarded as next-generation energy sources.

Solar cells may use a p-n junction, and may utilize various devices such as monocrystalline solar cells, polycrystalline solar cells, amorphous silicon solar cells, compound-based solar cells, dye-sensitized solar cells, etc., according to their materials, to improve efficiency and characteristics. Among these solar cells, crystalline silicon solar cells may use high cost materials and may involve complicated processing procedures, compared to power generation efficiency. Thus, interest in thin film solar cells having low cost of production has increased.

### SUMMARY

Embodiments are directed to a solar cell module, including a substrate, a lower electrode on the substrate, a light absorption layer on the lower electrode, an upper electrode on the light absorption layer, and a protective layer on the upper electrode, the protective layer extending along sidewalls of the light absorption layer to the lower electrode, the protective layer including a moisture absorbing material.

The light absorption layer may include at least one selected from the group of a CIS material, a CIGS material, an amorphous silicon material, and a CdTe material.

The solar cell module may further include first and second ribbons on the lower electrode, and the light absorption layer and the upper electrode may be between the first and second ribbons.

The protective layer may be on an upper surface and sidewalls of each of the first and second ribbons.

The moisture absorbing material may be a metal or metal oxide.

The moisture absorbing material may include at least one selected from the group of aluminum, magnesium, manganese, iron, calcium, barium, and strontium.

The solar cell module may further include a cover substrate on the protective layer, and the protective layer may have a refractive index that ranges from a refractive index of the cover substrate to a refractive index of the upper electrode.

The solar cell module may further include an encapsulation layer between the cover substrate and the protective layer, the encapsulation layer contacting the substrate.

The encapsulation layer may include at least one selected from the group of an ethylene vinyl acetate copolymer resin, a polyvinyl butyral resin, an ethylene vinyl acetate partial oxide resin, a silicon resin, an ester-based resin, and an olefin-based resin.

Embodiments are also directed to a method of manufacturing a solar cell module, the method including forming a lower electrode on a substrate, forming a light absorption layer on the lower electrode, forming an upper electrode on the light absorption layer, and forming a protective layer on the upper electrode, the protective layer being formed to extend along sidewalls of the light absorption layer to the lower electrode, the protective layer including a moisture absorbing material.

Forming the protective layer may include removing a portion of the light absorption layer and the upper electrode to expose a portion of the lower electrode, and forming the protective layer on the exposed portion of the lower electrode.

The light absorption layer may include at least one selected from the group of a CIS material, a CIGS material, an amorphous silicon material, and a CdTe material.

The method may further include forming first and second ribbons on the lower electrode, and the light absorption layer and the upper electrode may be between the first and second ribbons.

Forming the first and second ribbons may include removing portions of the protective layer to expose first and second portions of the lower electrode, and forming the first and second ribbons on the respective first and second portions of the lower electrode.

The protective layer may be formed on an upper surface and sidewalls of each of the first and second ribbons.

The moisture absorbing material may be a metal or metal oxide.

The method may include providing a cover substrate on the protective layer, and the protective layer may have a refractive index that ranges from a refractive index of the cover substrate to a refractive index of the upper electrode.

The moisture absorbing material may be a metal oxide, and forming the protective layer may include adjusting a partial pressure of oxygen when depositing the metal oxide.

The method may further include forming an encapsulation layer between the cover substrate and the protective layer, the encapsulation layer contacting the substrate.

The encapsulation layer may include at least one selected from the group of an ethylene vinyl acetate copolymer resin, a polyvinyl butyral resin, an ethylene vinyl acetate partial oxide, a silicon resin, an ester-based resin, and an olefin-based resin.

### BRIEF DESCRIPTION OF THE DRAWINGS

Features will become apparent to those of skill in the art by describing in detail example embodiments with reference to the attached drawings in which:

FIG. 1 illustrates a schematic cross-sectional view of a thin film solar cell module according to an example embodiment;

FIG. 2 illustrates a graph of light reflectivity of the thin film solar cell module of FIG. 1;

FIGS. 3 through 9 illustrate cross-sectional views of stages in a method of manufacturing the thin film solar cell module of FIG. 1 according to an example embodiment;

FIG. 10 illustrates a modified example of the thin film solar cell module of FIG. 1 according to another example embodiment; and

FIGS. 11 through 13 illustrate cross-sectional views stages in a method of manufacturing the thin film solar cell module of FIG. 10 according to an example embodiment.

### DETAILED DESCRIPTION OF THE INVENTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art. In the drawing figures, dimensions may be exaggerated for clarity of illustration. Like reference numerals refer to like elements throughout.

Elements may be exaggerated, omitted or schematically illustrated for convenience and clarity of description, and sizes thereof do not fully reflect actual sizes. Also, in the description of the elements, in the case where an element is referred to as being “on” or “under” another element, the element may be “directly” or “indirectly” on or under the other element or intervening elements. The term “on” or “under” is described with respect to the drawings.

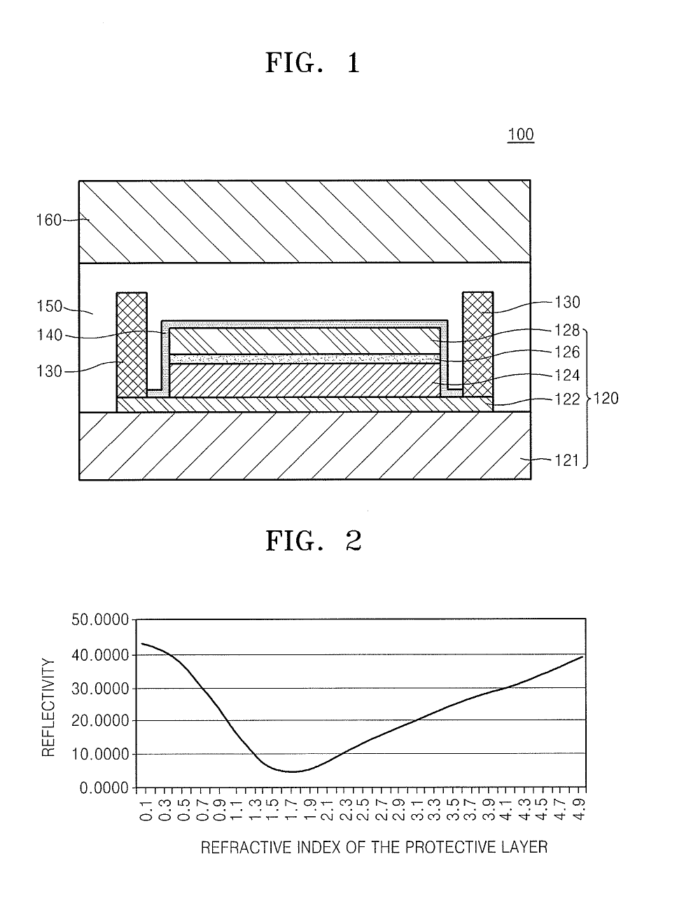

FIG. 1 illustrates a schematic cross-sectional view of a thin film solar cell module according to an example embodiment, and FIG. 2 illustrates a graph of light reflectivity of the thin film solar cell module of FIG. 1.

Referring to FIG. 1, a thin film solar cell module 100 according to an example embodiment may include a thin film solar cell 120, a protective layer 140 formed on the thin film solar cell 120, a pair of ribbons 130 each attached to one of both ends of the thin film solar cell 120, an encapsulation layer 150 that seals the thin film solar cell 120 and the pair of ribbons 130, and a cover substrate 160 disposed on the encapsulation layer 150.

The thin film solar cell 120 may directly transform solar light energy into electric energy by using a photoelectric effect, and may be a CIS-based thin film solar cell, an amorphous silicon thin film solar cell, a CdTd thin film solar cell, etc. For convenience, the thin film solar cell 120 may be hereinafter referred to as a CIGS thin film solar cell, but the thin film solar cell 120 may be the amorphous silicon thin film solar cell, the CdTd thin film solar cell, etc.

The thin film solar cell 120 may include a lower substrate 121, and a rear electrode layer 122, a light absorption layer 124, a buffer layer 126, and a transparent electrode layer 128 that are sequentially stacked on the lower substrate 121.

The lower substrate 121 may be, e.g., a glass substrate, a stainless steel substrate, a polymer substrate, etc. For example, the glass substrate may use soda lime glass, the polymer substrate may use polyimide, etc.

The rear electrode layer 122 may be formed of a metallic material having excellent conductivity and light reflectivity such as molybdenum (Mo), aluminum (Al) or copper (Cu) in order to collect charges formed by the photoelectric effect, and to reflect light that is transmitted through the light absorption layer 124 to allow the light absorption layer 124 to reabsorb the light. For example, the rear electrode layer 122 may be formed of molybdenum (Mo) in consideration of high conductivity, an ohmic contact with the light absorption layer 124, a high temperature stability in an atmosphere of selenium (Se), etc. Also, the rear electrode layer 122 may be formed as a multilayer so as to secure a junction with the lower substrate 121 and a resistance characteristic of the rear electrode layer 122.

The light absorption layer 124 absorbs incident solar light, and may be formed of, e.g., a copper-indium-selenium (CIS)-based compound including copper (Cu), indium (In), and selenium (Se) to form a p-type semiconductor layer. In another implementation, the light absorption layer 124 may be formed of a copper-indium-gallium-selenium (Cu(In,Ga)Se₂ (CIGS)-based compound including copper (Cu), indium (In), gallium (Ga), and selenium (Se). The light absorption layer 124 may be foamed to have a thickness of, e.g., about 0.7 μm to about 2 μm.

The buffer layer 126 may reduces a band gap difference between the light absorption layer 124 and the transparent electrode layer 128, which is described below. The buffer layer 126 may reduce recombination of electrons and holes that may occur on an interface between the light absorption layer 124 and the transparent electrode layer 128. The buffer layer 126 may be formed of, e.g., CdS, ZnS, In₂S₃, ZnₓMg₍₁₋ₓ₎O, etc.

The transparent electrode layer 128 may constitute a P-N junction and may be formed of a conductive material having a property capable of transmitting light such as ZnO:B, ZnO:Al, ZnO:Ga, indium tin oxide (ITO), indium zinc oxide (IZO), etc. Thus, the transparent electrode layer 128 may transmit incident light and simultaneously collect charges formed by the photoelectric effect.

The protective layer 140 may be formed on the thin film solar cell 120. For example, the protective layer 140 may be formed on a top surface of the transparent electrode layer 128, and may be formed to cover a part of a top surface of the rear electrode layer 122 which is exposed during a process of attaching the pair of ribbons 130 and side surfaces of the light absorption layer 124, the buffer layer 126, and the transparent electrode layer 128.

The protective layer 140 may be formed of a moisture absorbing material. For example, the protective layer 140 may be formed of Al₂O₃, MgO, etc. The protective layer may include one or more of, e.g., aluminum (Al), magnesium (Mg), manganese (Mn), iron (Fe), calcium (Ca), barium (Ba), strontium (Sr), oxides thereof, etc. The protective layer 140 may absorb moisture that penetrates into the thin film solar cell module 100, and thus the thin film solar cell 120 may be protected from moisture that penetrates into the thin film solar cell module 100.

A refractive index of the protective layer 140 may be a value between a refractive index of the cover substrate 160 and a refractive index of the transparent electrode layer 128 in order to minimize reflection, by the protective layer 140, of solar light incident to a front surface of the cover substrate 160.

For example, the cover substrate 160 may be formed of a glass material having a refractive index of about 1.5, the transparent electrode layer 128 may be formed of ITO having a refractive index of about 2, and the protective layer 140 may be formed to have a refractive index of about 1.5 to about 2. In an implementation, a refractive index of the encapsulation layer 150, which may be formed of ethylene-vinyl acetate copolymer resin, may be set to be same as a refractive index of the cover substrate 160, and thus when setting a refractive index of the protective layer 140, the refractive index of the encapsulation layer 150 may not have a significant effect.

FIG. 2 illustrates a reflectivity of the thin film solar cell module 100 according to a refractive index of the protective layer 140 obtained from a light reflectivity equation of a multi-layer structure when refractive indices of the cover substrate 160 and the encapsulation layer 150 are about 1.5 and a refractive index of the transparent electrode layer 128 is about 2. As shown in FIG. 2, when a refractive index of the protective layer 140 has a value between the refractive index of the cover substrate 160 and the refractive index of the transparent electrode layer 128, the reflectivity of solar light incident to a top surface of the cover substrate 160 may be minimized, and thus an amount of light arriving to the light absorption layer 124 may be increased.

A thickness of the protective layer 140 may be, e.g., about 50 nm to about 1000 nm. Maintaining the thickness of the protective layer 140 at about 50 nm or more may help ensure an effect of absorbing the moisture penetrated into the thin film solar cell module 100. Maintaining a thickness of the protective layer 140 at about 1000 nm or less may help avoid reductions in an amount of light penetrated to the solar cell as a light absorptivity of the moisture absorbing material is increased. Thus, a thickness of the protective layer 140 may be in a range of about 50 nm to about 1000 nm.

The protective layer 140 according to an example embodiment may absorb the moisture penetrated into the thin film solar cell module 100, and thus moisture penetrating into the thin film solar cell 120 may be prevented, and at the same time, a photoelectric conversion efficiency of the thin film solar cell 120 may be improved as the protective layer 140 serves as a antireflection film.

The pair of ribbons 130 may be attached onto the rear electrode layer 122 exposed at both sides of the thin film solar cell 120. The pair of ribbons 130 may be conductive, and may collect electrons and holes that are generated in the thin film solar cell 120. The ribbons 130 may be connected to a lead line of a junction box (not shown) that prevents a counter flow of current.

The encapsulation layer 150 may be disposed between the pair of ribbons 130 and may seal the thin film solar cell 120, together with the pair of ribbons 130, thereby blocking moisture or oxygen that may adversely affect the thin film solar cell 120.

The encapsulation layer 150 may be formed of, e.g., ethylene vinyl acetate (EVA) copolymer resin, polyvinyl butyral (PVB), EVA partial oxide, silicone resin, ester-based resin, olefin-based resin, etc. The encapsulation layer 150 may seal the thin film solar cell 120 and the pair of ribbons 130, and may block moisture and oxygen that may damage the thin film solar cell 120.

The cover substrate 160 may be formed of, e.g., glass, such that sunlight may be transmitted through the cover substrate 160, and may be formed of tempered glass so as to protect the thin film solar cell 120 from an external shock, etc. The cover substrate 160 may be formed of low iron tempered glass so as to help prevent solar light from being reflected and increase transmittance of solar light.

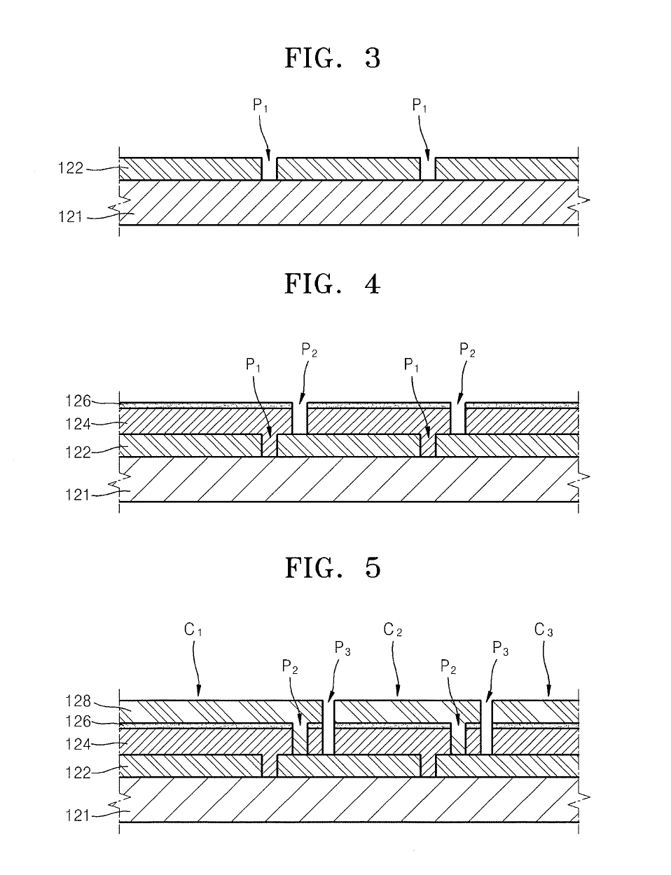

FIGS. 3 through 9 illustrate cross-sectional views of stages in a method of manufacturing the thin film solar cell module of FIG. 1 according to an example embodiment.

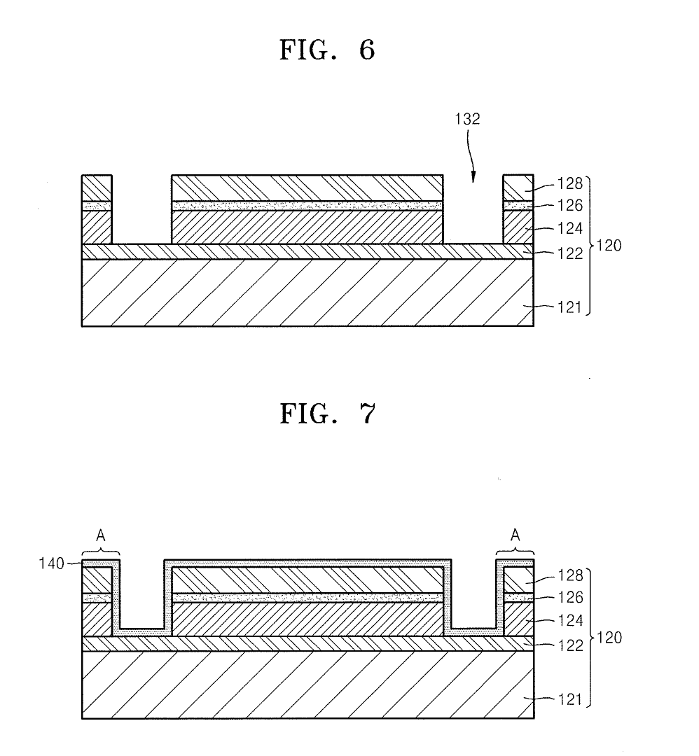

FIGS. 3 through 9 are detailed views of an example structure of the thin film solar cell 120 and the method of manufacturing the thin film solar cell module 100 of FIG. 1 according to an example embodiment. FIGS. 6 through 9 are views for explaining the example method of manufacturing the thin film solar cell module 100 by using the thin film solar cell 120 manufactured in FIGS. 3 through 5.

A method of manufacturing the thin film solar cell 120 according to an example embodiment will now be described with reference to FIGS. 3 through 5.

Referring to FIG. 3, the rear electrode layer 122 may be formed on the lower substrate 121, first patterning may be performed thereon, and the rear electrode layer 122 may be split into a plurality of layers.

The rear electrode layer 122 may be formed by, e.g., applying a conductive paste on the lower substrate 121 and thermally processing the conductive paste, or through processing such as plating. In an implementation, the rear electrode layer 122 may be formed through sputtering using, e.g., a molybdenum (Mo) target.

The first patterning may use, for example, laser scribing. The laser scribing may be performed by irradiating a laser from a bottom surface of the lower substrate 121 to the lower substrate 121 and evaporating a part of the rear electrode layer 122, or by irradiating a laser from a top surface of the rear electrode layer 122 and evaporating a part of the rear electrode layer 122, and thus a first pattern portion P1 that splits the rear electrode layer 122 into the plurality of layers with uniform gaps therebetween may be formed.

Thereafter, referring to FIG. 4, the light absorption layer 124 and the buffer layer 126 may be formed, and then second patterning may be performed thereon.

The light absorption layer 124 may be formed using, e.g., a co-evaporation method of heating copper (Cu), indium (In), gallium (Ga), and selenium (Se) contained in a small electric furnace installed in a vacuum chamber and performing a vacuum and evaporation process thereon. The light absorption layer 124 may be formed using, e.g., a sputtering/selenization method of forming a CIG-based metal precursor layer on the rear electrode layer 122 by using a copper (Cu) target, an indium (In) target, and a gallium (Ga) target, thermally processing the CIG-based metal precursor layer in an atmosphere of hydrogen selenium (H₂Se), and reacting the CIG-based metal precursor layer with selenium (Se). In an implementation, the light absorption layer 124 may be formed using an electro-deposition method, a metalorganic chemical vapor deposition (MOCVD) method, etc.

The buffer layer 126 may be formed using, e.g., a chemical bath deposition (CBD) method, an atomic layer deposition (ALD) method, an ion layer gas reaction (ILGAR) method, etc.

In this regard, the second patterning may use, for example, mechanical scribing that is performed to form a second pattern portion P2 by moving a sharp tool such as a needle in a direction parallel to the first pattern portion P1 at a point spaced apart from the first pattern portion P1. In another implementation, the second patterning may use laser scribing.

The second pattern portion P2 may split the light absorption layer 124 into a plurality of layers, and may extend to a top surface of the rear electrode layer 122 to allow the rear electrode layer 122 to be exposed.

Referring to FIG. 5, the transparent electrode layer 128 may be formed, and third patterning may be performed.

The transparent electrode layer 128 may be formed of, e.g., a transparent and conductive material such as ZnO:B, ZnO:Al, ZnO:Ga, indium tin oxide (ITO), indium zinc oxide (IZO), etc., and may be formed using a metalorganic chemical vapor deposition (MOCVD), a low pressure chemical vapor deposition (LPCVD), a sputtering method, etc.

The transparent electrode layer 128 may be formed in the second pattern portion P2 to contact the rear electrode layer 122 exposed by the second pattern portion P2, and may electrically connect the light absorption layer 124 split into the plurality of layers by the second pattern portion P2.

The transparent electrode layer 128 may be split into a plurality of layers by a third pattern portion P3 formed at a location different from the first pattern portion P1 and the second pattern portion P2.

The third patterning may use, e.g., laser scribing or mechanical scribing. The third pattern portion P3 formed by performing the third patterning may be a groove formed in parallel with the first pattern portion P1 and the second pattern portion P2, and may extend to the top surface of the rear electrode layer 122. Thus, a plurality of photoelectric conversion units C1˜C3 may be formed. Also, the third pattern portion P3 may act as an insulation layer between the photoelectric conversion units C1˜C3, and the photoelectric conversion units C1˜C3 may be connected in series with each other.

An example method of manufacturing the thin film solar cell module 100 of FIG. 1 will now be described with reference to FIGS. 6 through 9.

Referring to FIG. 6, edge deletion may be performed on the thin film solar cell 120, and then the top surface of the rear electrode layer 122 may be exposed to attach the pair of ribbons 130 thereto. For example, after the edge deletion is performed, openings 132 exposing the rear electrode layer 122 may be formed at both ends of the rear electrode layer 122. The openings 132 may be grooves that are formed in parallel with the first through third pattern portions P1 through P3. The ribbons 130 may be disposed in the openings 132, and thus a width of the openings 132 may be at least as great as a width of the ribbons 130. The openings 132 may be formed using, e.g., mechanical scribing, laser scribing, a selective etching process, etc.

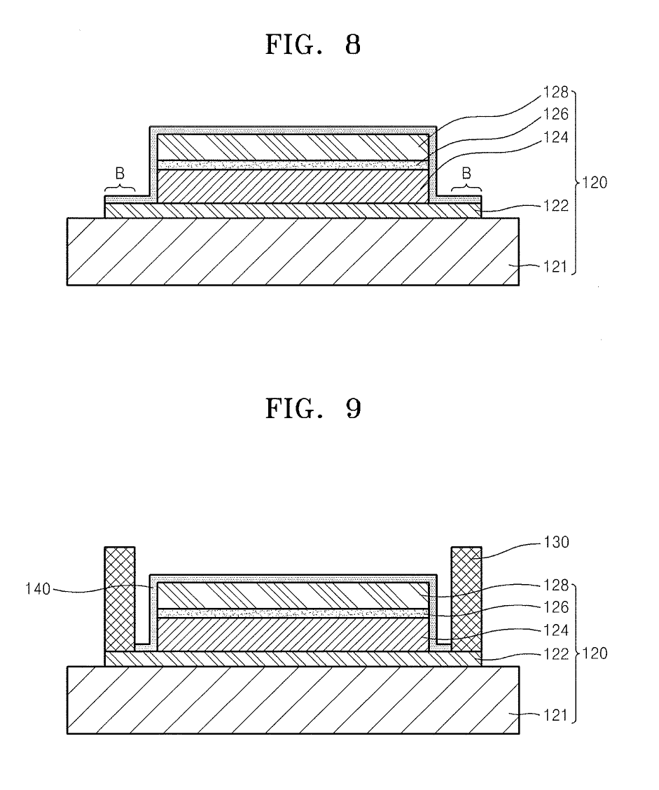

Subsequently, as shown in FIG. 7, the protective layer 140 may be formed over the entire structure shown in FIG. 6.

The protective layer 140 may be formed of, e.g., Al₂O₃ or MgO to absorb the moisture penetrated into the thin film solar cell module 100. A refractive index of the protective layer 140 may be controlled by, e.g., controlling oxygen partial pressure when depositing Al₂O₃ or MgO. For example, when the protective layer 140 is formed of Al₂O₃, a refractive index of the protective layer 140 is lowered as the oxygen partial pressure is increased when depositing an Al₂O₃ thin film. Thus, a refractive index of the protective layer 140 may be changed, and the protective layer 140 may have a refractive index value between refractive indices of the cover substrate 160 and the transparent electrode layer 128 in consideration of values of the refractive indices of the cover substrate 160 and the transparent electrode layer 128.

The protective layer 140 may be formed by using, e.g., a sputtering method, a low pressure chemical vapor deposition (LPCVD) method, a metalorganic chemical vapor deposition (MOCVD) method, a plasma enhanced chemical vapor deposition (PECVD) method, an atomic layer deposition (ALD) method, a spin coating method, a printing method, etc. The protective layer 140 may be formed at a temperature of, e.g., about 200° C. or less in order to help prevent thermal damage to the buffer layer 126 and the transparent electrode layer 128.

After forming the protective layer 140, an edge deletion process may be performed as shown in FIG. 8. The edge deletion process may be performed on all the edges of the thin film solar cell module 120 and may remove portions ‘A’ of FIG. 7. The thin film solar cell 120 formed on the edges of the lower substrate 121 may be removed, and thus a bonding force between the encapsulation layer 150 (formed later) and the lower substrate 121 may be increased, and the thin film solar cell 120 may be prevented from being exposed to an external environment.

Next, as shown in FIG. 9, an electrode exposure process for removing portions ‘B’ of FIG. 8 may be performed to expose ends of the rear electrode layer 122. In another implementation, the order of the electrode exposure process and the edge deletion process may be switched.

After the electrode exposure process, the pair of ribbons 130 may be attached on the exposed rear electrode layer 122. The pair of ribbons 130 may be attached on the exposed rear electrode layer 122 by, e.g., coating a flux on the exposed rear electrode layer 122, disposing the pair of ribbons 130 on the flux, and performing a tabbing process through heat treatment. In another implementation, the pair of ribbons 130 may be attached on the rear electrode layer 122 by, e.g., using a conductive tape, an ultrasonic welding process, an ultrasonic soldering process, etc. When the pair of ribbons 130 are attached to the rear electrode layer 122 by an ultrasonic welding process or an ultrasonic soldering process, the edge deletion process of FIG. 8 may be omitted.

The pair of ribbons 130 may be disposed in the openings 132 of FIG. 6 as shown and described in relation to FIG. 6. The pair of ribbons 130 may be formed along a direction of the openings 132 of FIG. 6.

After attaching the pair of ribbons 130, the encapsulation layer 150 and the cover substrate 160 of FIG. 1 may be disposed to form the thin film solar cell module 100 as shown in FIG. 1 through laminating. The thin film solar cell module 100 formed in such a manner is laminated.

The encapsulation layer 150 may help prevent external moisture penetration, and the protective layer 140 may also absorb moisture penetrated into the thin film solar cell module 100, and thus moisture may not penetrate into the thin film solar cell 120. Therefore, a general edge sealing unit may be omitted. Also, the protective layer 140 may serve as an antireflection film, and a photoelectric conversion efficiency may be improved.

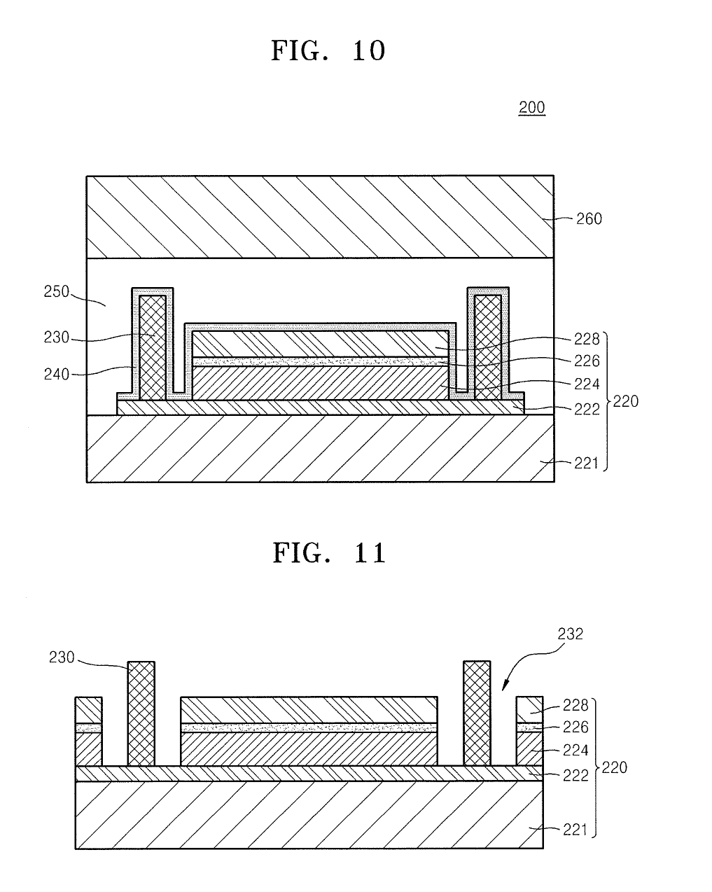

FIG. 10 illustrates a modified example of the thin film solar cell module of FIG. 1 according to another example embodiment.

Referring to FIG. 10, a thin film solar cell module 200 according to the present example embodiment may include a thin film solar cell 220, a pair of ribbons 230 each attached to an end of the thin film solar cell 220, a protective layer 240 formed on the thin film solar cell 220 and the pair of ribbons 230, an encapsulation layer 250 formed on the protective layer 240, and a cover substrate 260 on the encapsulation layer 250.

The thin film solar cell 220 may be, for example, a CIGS thin film solar cell, and the thin film solar cell 220 may include a lower substrate 221, and a rear electrode layer 222, a light absorption layer 224, a buffer layer 226, and a transparent electrode layer 228 that are sequentially stacked on the lower substrate 221.

The thin film solar cell 220, the encapsulation layer 250, and the cover substrate 260 may be the same as the thin film solar cell 120, the encapsulation layer 150, and the cover substrate 160 that are shown and described in FIG. 1, and thus details thereof will not be repeated, and differences therebetween will be described hereinafter.

Referring to FIG. 10, the protective layer 240 may be formed to cover the pair of ribbons 230. For example, the protective layer 240 may be formed to cover a top surface of the transparent electrode layer 228, side surfaces of the light absorption layer 224, the buffer layer 226, and the transparent electrode layer 228, a part of a top surface of the rear electrode layer 222, and a top surface and both side surfaces of each of the pair of ribbons 230. Sealing surfaces of the pair of ribbons 230 with the protective layer 240 having a moisture absorbing effect may help prevent corrosion of the pair of ribbons 230.

In an implementation, the protective layer 240 may have a refractive index value between refractive indices of the transparent electrode layer 228 and the cover substrate 260, and thus the protective layer 240 may serve as an antireflection film at the same time and may improve a photoelectric conversion efficiency of the thin film solar cell 220.

FIGS. 11 through 13 illustrate cross-sectional views stages in a method of manufacturing the thin film solar cell module of FIG. 10 according to an example embodiment.

The thin film solar cell 220 of the thin film solar cell module 200 may be the same as the thin film solar cell 120 shown and described in FIG. 1. Accordingly, the method of manufacturing the thin film solar cell 220 may be the same as the method of manufacturing the thin film solar cell 120 shown and described in FIGS. 3 through 6, and thus details thereof will not be repeated, and differences therebetween will be described hereinafter.

Referring to FIGS. 11 through 13 to describe the method of manufacturing the thin film solar cell module 200 of FIG. 10, first, the rear electrode layer 222, the light absorption layer 224, the buffer layer 226, and the transparent electrode layer 228 may be sequentially stacked on the lower substrate 221 as shown in FIG. 11 to form the thin film solar cell 220. Then, openings 232 exposing the rear electrode layer 222 may be formed at sides of the thin film solar cell 220, and the ribbons 230 may each be attached to the top surface of the rear electrode layer 222 exposed by the openings 232.

The openings 232 may be formed using, e.g., mechanical scribing, laser scribing, a selective etching process, etc. Since the ribbons 230 are to be disposed in the openings 232, a width of the openings 232 may be formed at least as large as a width of the ribbons 230.

The pair of ribbons 230 may be attached to the rear electrode layer 222 through, e.g., a tabbing process, using a conductive tape, an ultrasonic welding process, an ultrasonic soldering process, etc.

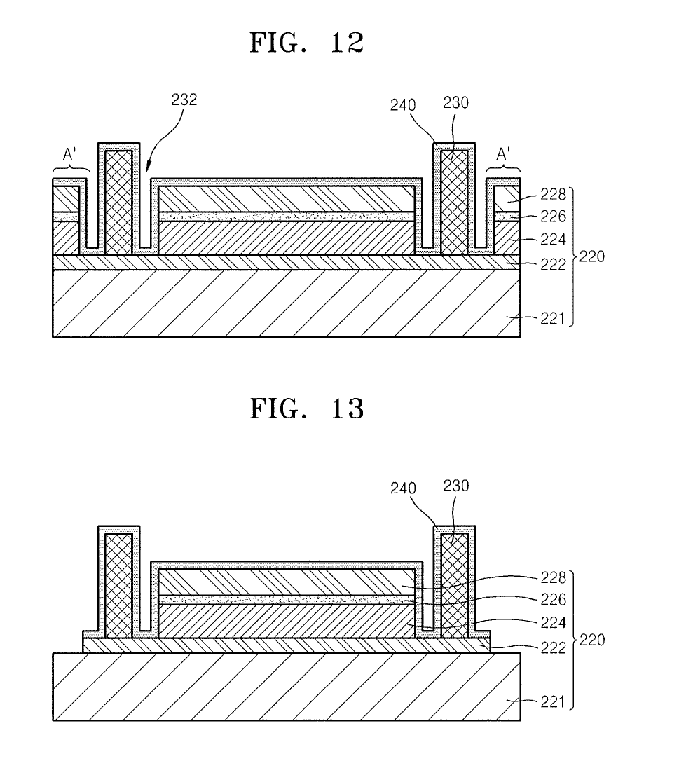

After forming the pair of ribbons 230, the protective layer 240 may be formed in the same manner as in FIG. 12. The protective layer 240 may be formed by using, e.g., a sputtering method, a low pressure chemical vapor deposition (LPCVD) method, a metalorganic chemical vapor deposition (MOCVD) method, a plasma enhanced chemical vapor deposition (PECVD) method, an atomic layer deposition (ALD) method, a spin coating method, a printing method, etc. The protective layer 240 may be formed at a temperature of, e.g., 200° C. or less in order to help prevent thermal damage to the buffer layer 226 and the transparent electrode layer 228.

Next, an edge deletion process may be performed as shown in FIG. 13.

The edge deletion process may be performed on all the edges of the thin film solar cell module 220 and may remove portions A′ of FIG. 12. The thin film solar cell 220 formed on the edges of the lower substrate 221 may be removed, and thus a bonding force between the encapsulation layer 250 (formed later) and the lower substrate 221 may be increased, and the thin film solar cell 220 may be prevented from being exposed to an external environment.

Subsequently, after disposing the encapsulation layer 250 and the cover substrate 260, the thin film solar cell module 200 of FIG. 10 may be formed through a lamination process.

The encapsulation layer 250 may help prevent external moisture penetration, and the protective layer 240 may absorb moisture penetrated into the thin film solar cell module 200, and thus moisture may not penetrate into the thin film solar cell 220. The protective layer 240 may be formed to cover the pair of ribbons 230, which may help prevent corrosion of the pair of ribbons 230. Moreover, the protective layer 240 may serve as an antireflection film at the same time, and thus a photoelectric conversion efficiency of the thin film solar cell 220 may be improved.

By way of summation and review, thin film solar cell modules may include thin film solar cells. In a general method, an edge sealing operation may be performed between a lower substrate and a cover substrate so as to protect the thin film solar cells from external moisture, etc.

As described above, embodiments may provide a thin film solar cell module configured to help prevent moisture penetration and improve a photoelectric conversion efficiency even when edge sealing is omitted, and a method of manufacturing the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. For example, a thin film solar cell module according to embodiments is not limited to the configurations and the methods of the embodiments described above, and whole or parts of each of the embodiments may be selectively combined to make various modifications. Accordingly, it will be understood by those of skill in the art that various changes in form and details may be made without departing from the spirit and scope of the present invention as set forth in the following claims.

What is claimed is:

1. A solar cell module, comprising:
a substrate;
a lower electrode on the substrate;
a light absorption layer on the lower electrode;
an upper electrode on the light absorption layer; and
a protective layer on the upper electrode, the protective layer extending along sidewalls of the light absorption layer to the lower electrode, the protective layer including a moisture absorbing material.

2. The solar cell module as claimed in claim 1, wherein the light absorption layer includes at least one selected from the group of a CIS material, a CIGS material, an amorphous silicon material, and a CdTe material.

3. The solar cell module as claimed in claim 1, further comprising first and second ribbons on the lower electrode, wherein the light absorption layer and the upper electrode are between the first and second ribbons.

4. The solar cell module as claimed in claim 3, wherein the protective layer is on an upper surface and sidewalls of each of the first and second ribbons.

5. The solar cell module as claimed in claim 1, wherein the moisture absorbing material is a metal or metal oxide.

6. The solar cell module as claimed in claim 5, wherein the moisture absorbing material includes at least one selected from the group of aluminum, magnesium, manganese, iron, calcium, barium, and strontium.

7. The solar cell module as claimed in claim 5, further comprising a cover substrate on the protective layer, wherein the protective layer has a refractive index that ranges from a refractive index of the cover substrate to a refractive index of the upper electrode.

8. The solar cell module as claimed in claim 7, further comprising an encapsulation layer between the cover substrate and the protective layer, the encapsulation layer contacting the substrate.

9. The solar cell module as claimed in claim 8, wherein the encapsulation layer includes at least one selected from the group of an ethylene vinyl acetate copolymer resin, a polyvinyl butyral resin, an ethylene vinyl acetate partial oxide resin, a silicon resin, an ester-based resin, and an olefin-based resin.

10. A method of manufacturing a solar cell module, the method comprising:
forming a lower electrode on a substrate;
forming a light absorption layer on the lower electrode;
forming an upper electrode on the light absorption layer; and
forming a protective layer on the upper electrode, the protective layer being formed to extend along sidewalls of the light absorption layer to the lower electrode, the protective layer including a moisture absorbing material.

11. The method as claimed in claim 10, wherein forming the protective layer includes:
removing a portion of the light absorption layer and the upper electrode to expose a portion of the lower electrode, and
forming the protective layer on the exposed portion of the lower electrode.

12. The method as claimed in claim 10, wherein the light absorption layer includes at least one selected from the group of a CIS material, a CIGS material, an amorphous silicon material, and a CdTe material.

13. The method as claimed in claim 10, further comprising forming first and second ribbons on the lower electrode, wherein the light absorption layer and the upper electrode are between the first and second ribbons.

14. The method as claimed in claim 13, wherein forming the first and second ribbons includes:
removing portions of the protective layer to expose first and second portions of the lower electrode, and
forming the first and second ribbons on the respective first and second portions of the lower electrode.

15. The method as claimed in claim 13, wherein the protective layer is formed on an upper surface and sidewalls of each of the first and second ribbons.

16. The method as claimed in claim 10, wherein the moisture absorbing material is a metal or metal oxide.

17. The method as claimed in claim 16, further comprising providing a cover substrate on the protective layer, wherein the protective layer has a refractive index that ranges from a refractive index of the cover substrate to a refractive index of the upper electrode.

18. The method as claimed in claim 17, wherein the moisture absorbing material is a metal oxide, and forming the protective layer includes adjusting a partial pressure of oxygen when depositing the metal oxide.

19. The method as claimed in claim 10, further comprising forming an encapsulation layer between the cover substrate and the protective layer, the encapsulation layer contacting the substrate.

20. The method as claimed in claim 19, wherein the encapsulation layer includes at least one selected from the group of an ethylene vinyl acetate copolymer resin, a polyvinyl butyral resin, an ethylene vinyl acetate partial oxide, a silicon resin, an ester-based resin, and an olefin-based resin.
